(19) United States
(12) Patent Application Publication
(10) Pub. No.: US 2014/0252500 A1
(43) Pub. Date: Sep. 11, 2014

(54) SACRIFICIAL REPLACEMENT EXTENSION LAYER TO OBTAIN ABRUPT DOPING PROFILE

(71) Applicant: INTERNATIONAL BUSINESS MACHINES CORPORATION, (US)

(72) Inventors: Szu-Lin Cheng, Yorktown Heights, NY (US); Jack O. Chu, Manhasset Hills, NY (US); Isaac Lauer, Yorktown Heights, NY (US); Jeng-Bang Yau, Yorktown Heights, NY (US)

(73) Assignee: INTERNATIONAL BUSINESS MACHINES CORPORATION, Armonk, NY (US)

(21) Appl. No.: 13/791,475

(22) Filed: Mar. 8, 2013

(51) Int. Cl. H01L 29/78; H01L 29/66

(52) U.S. Cl. CPC H01L 29/7833; H01L 29/66492
USPC 257/408; 438/300

(57) ABSTRACT

At least one gate structure having a first spacer located on a vertical sidewall thereof is provided on an uppermost surface of a semiconductor substrate. Exposed portions of the semiconductor substrate are then removed utilizing the at least one gate structure and first spacer as an etch mask. A sacrificial replacement material is formed on each recessed surface of the semiconductor substrate. Next, a second spacer is formed contacting the first spacer. Source/drain trenches are then provided by removing exposed portions of the sacrificial replacement material and an underlying portion of the semiconductor substrate. Remaining sacrificial replacement material located beneath the second spacer is removed providing an opening beneath the second spacer. A doped semiconductor material is formed within the source/drain trenches and the opening.

### BACKGROUND

The present disclosure relates to a semiconductor structure and a method of forming the same. More particularly, the present disclosure relates to a semiconductor structure having an abrupt source/drain extension profile and a method of forming the same.

As semiconductor devices shrink in each generation of semiconductor technology, it is more desirable to achieve step-function like source/drain extension profiles and high doping concentrations (on the order of 10²¹ atoms/cm³ or greater) for better device performance as well as process control. By “step-like source/drain extension profiles” it is meant to be atomically or near-atomically abrupt doping transitions.

Typical source/drain extension profiles formed by ion implantation or atomic layer doping are now insufficient. Extensions formed by ion implantation have a Guassian like profile, while atomic layer doping requires a drive-in anneal and usually afterwards the dopant-profile will lose its abruptness. Moreover, any additional thermal processing which is performed after the formation of the source/drain extensions can further decrease the profile abruptness.

There is thus a need to provide a method to improve and control the extension profile, which is compatible to device scaling.

### SUMMARY

The present disclosure provides a method to improve and control the source/drain extension profile, which is compatible with device scaling. More particularly, the present disclosure provides a method to provide a semiconductor structure with step-function like source/drain extension profiles and high doping concentrations (on the order of 10²¹ atoms/cm³ or greater). The above can be achieved in the present disclosure by utilizing a method which includes using a sacrificial replacement material.

In one aspect of the present disclosure, a method of forming a semiconductor structure is provided. The method includes first providing at least one gate structure on an uppermost surface of a semiconductor substrate. In accordance with the present disclosure, a first spacer is located on a vertical sidewall of the at least one gate structure and has a base contacting a portion of the uppermost surface of the semiconductor structure. Exposed portions of the semiconductor substrate are then removed utilizing the at least one gate structure and first spacer as an etch mask. A sacrificial replacement material is then formed on each recessed surface of the semiconductor substrate. Next, a second spacer is formed contacting the first spacer and having a base that is present on the uppermost surface of the sacrificial replacement material. Source/drain trenches are then provided by removing exposed portions of the sacrificial replacement material and an underlying portion of the semiconductor substrate utilizing the second spacer, the first spacer and the at least one gate structure as another etch mask, wherein a sacrificial replacement material portion remains beneath the second spacer. Next, the sacrificial replacement material portion is removed from beneath the second spacer to provide an opening beneath the second spacer and thereafter a doped semiconductor material is formed within the source/drain trenches and the opening located beneath the second spacer.

In another aspect of the present disclosure, a semiconductor structure having an abrupt source/drain extension profile is provided. By “abrupt” it is meant to have an atomically or near-atomically doping transition up to a 10²¹ doping concentrations. In accordance with the present disclosure, the structure includes a semiconductor substrate comprising at least one stepped mesa semiconductor structure and adjoining recessed surface semiconductor portions. A gate structure is located on an uppermost surface of the at least one stepped mesa semiconductor structure. A first spacer is present on vertical sidewalls of the gate structure and has a base in contact with the uppermost surface of the at least one stepped mesa semiconductor structure. A second spacer is located adjacent the first spacer, and a base of the second spacer is present on an uppermost surface of a source/drain extension region. The source/drain extension region has a bottommost surface located on a ledge portion of the at least one stepped mesa semiconductor structure. A source/drain region is located on each of the recessed surface semiconductor portions of the semiconductor substrate. In accordance with the present disclosure, the source/drain region and the source/drain extension region are of unitary construction and comprise a same doped semiconductor material, and the source/drain extension region is located from 10 nm or less from a channel region located within a portion of the at least one stepped mesa semiconductor structure and directly beneath the gate structure.

The method of the present disclosure can also be implemented for devices in which the source/drain extension region is located further from the channel region in the range of 10 nm to 30 nm.

### BRIEF DESCRIPTION OF THE DRAWINGS

FIG. 1 is a pictorial representation (through a cross sectional view) illustrating a structure including a plurality of gate structures located on an uppermost surface of a semiconductor substrate and a first spacer located on a vertical sidewall of each of the gate structures that can be employed in one embodiment of the present disclosure.

FIG. 2 is a pictorial representation (through a cross sectional view) illustrating the structure of FIG. 1 after recessing exposed portions of the semiconductor substrate utilizing the gate structures and first spacers as an etch mask.

FIG. 3 is a pictorial representation (through a cross sectional view) illustrating the structure of FIG. 2 after forming a sacrificial replacement material on each of the recessed surfaces.

FIG. 4 is a pictorial representation (through a cross sectional view) illustrating the structure of FIG. 3 after forming a second spacer contacting the first spacer and having a base that is present on the uppermost surface of the sacrificial replacement material.

FIG. 5 is a pictorial representation (through a cross sectional view) illustrating the structure of FIG. 4 after forming source/drain trenches by removing exposed portions of the sacrificial replacement material and an underlying portion of the semiconductor substrate.

FIG. 6 is a pictorial representation (through a cross sectional view) illustrating the structure of FIG. 5 after removing a sacrificial replacement material portion from beneath each second spacer to provide an opening beneath the second spacer.

FIG. 7 is a pictorial representation (through a cross sectional view) illustrating the structure of FIG. 6 after formation of a doped semiconductor material within the source/drain trenches and the opening located beneath the second spacer.

### DETAILED DESCRIPTION

The present disclosure will now be described in greater detail by referring to the following discussion and drawings that accompany the present application. It is noted that the drawings of the present application are provided for illustrative purposes and, as such, they are not drawn to scale. In the following description, numerous specific details are set forth, such as particular structures, components, materials, dimensions, processing steps and techniques, in order to provide a thorough understanding of the present disclosure. However, it will be appreciated by one of ordinary skill in the art that the present disclosure may be practiced with viable alternative process options without these specific details. In other instances, well-known structures or processing steps have not been described in detail in order to avoid obscuring the various embodiments of the present disclosure.

The present disclosure provides a method to improve and control the source/drain extension profile, which is compatible with device scaling. Notably, the method of the present disclosure includes providing at least one gate structure having a first spacer located on a vertical sidewall thereof on an uppermost surface of a semiconductor substrate. Exposed portions of the semiconductor substrate are then removed utilizing the at least one gate structure and first spacer as an etch mask. A sacrificial replacement material is formed on each recessed surface of the semiconductor substrate. Next, a second spacer is formed contacting the first spacer. Source/drain trenches are then provided by removing exposed portions of the sacrificial replacement material and an underlying portion of the semiconductor substrate. Remaining sacrificial replacement material located beneath the second spacer is removed providing an opening beneath the second spacer. A doped semiconductor material is formed within the source/drain trenches and the opening. The method of the present disclosure is now described in greater detail.

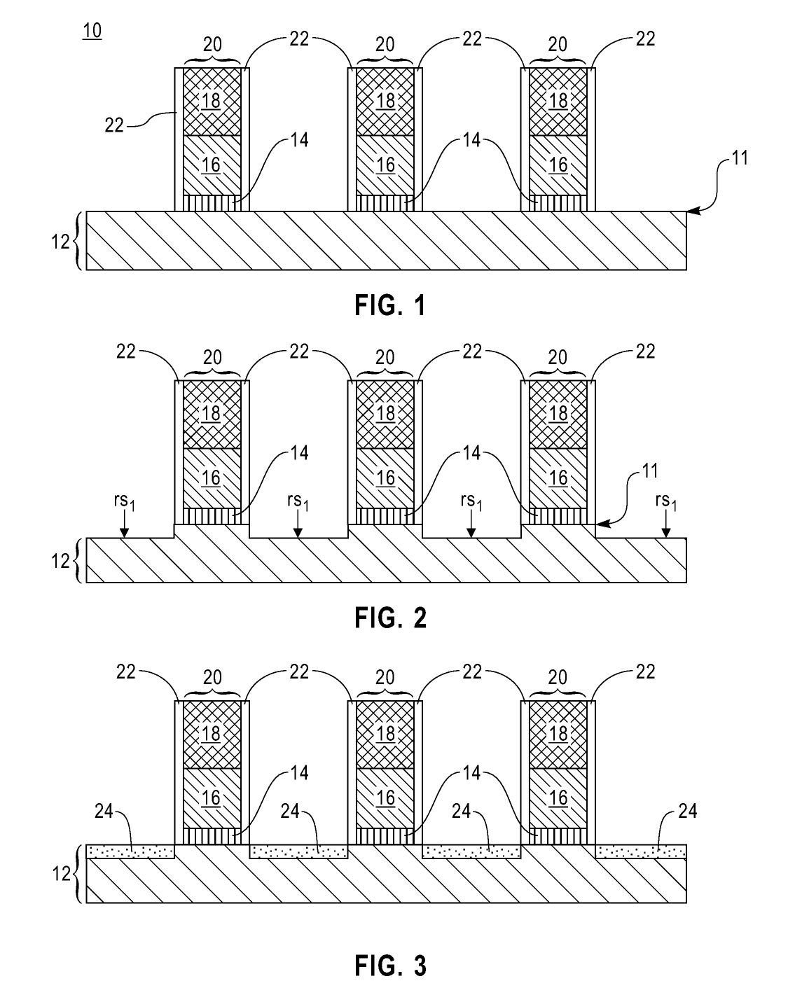

Referring first to FIG. 1, there is illustrated a structure 10 that can be employed in one embodiment of the present disclosure. The structure 10 that can be employed in the present disclosure includes a plurality of gate structures 20 located on an uppermost surface 11 of a semiconductor substrate 12. Although a plurality of gate structures 20 are described and illustrated, the method of the present disclosure works equally well when only a single gate structure is formed on the uppermost surface of the semiconductor substrate. The portion of the semiconductor substrate 12 that is located directly beneath each gate structure 20 can be referred to herein as a channel region of the semiconductor substrate 12. The channel regions are not shown in FIG. 1-6 of the present disclosure, however, the channel region 48 is shown within the semiconductor substrate of the central gate structure shown in FIG. 7. It is understood that equivalent channel regions would be present in the semiconductor substrate beneath each gate structure.

In some embodiments of the present disclosure, the semiconductor substrate 12 is a bulk semiconductor substrate. When a bulk semiconductor substrate is employed as semiconductor substrate 12, the bulk semiconductor substrate can be comprised of any semiconductor material including, but not limited to, Si, Ge, SiGe, SiC, SiGeC, InAs, GaAs, InP or other like III/V compound semiconductors. Multilayers of these semiconductor materials can also be used as the semiconductor material of the bulk semiconductor. In one embodiment, the semiconductor substrate 12 comprises a single crystalline semiconductor material, such as, for example, single crystalline silicon. In other embodiments, the semiconductor substrate 12 may comprise a polycrystalline or amorphous semiconductor material.

In another embodiment, a semiconductor-on-insulator (SOI) substrate (not specifically shown) is employed as the semiconductor substrate 12. When employed, the SOI substrate includes a handle substrate, a buried insulating layer located on an upper surface of the handle substrate, and a semiconductor layer located on an upper surface of the buried insulating layer. The handle substrate and the semiconductor layer of the SOI substrate may comprise the same, or different, semiconductor material. The term “semiconductor” as used herein in connection with the semiconductor material of the handle substrate and the semiconductor layer denotes any semiconducting material including, for example, Si, Ge, SiGe, SiC, SiGeC, InAs, GaAs, InP or other like III/V compound semiconductors. Multilayers of these semiconductor materials can also be used as the semiconductor material of the handle substrate and the semiconductor layer. In one embodiment, the handle substrate and the semiconductor layer are both comprised of silicon. In another embodiment, hybrid SOI substrates are employed which have different surface regions of different crystallographic orientations.

The handle substrate and the semiconductor layer may have the same or different crystal orientation. For example, the crystal orientation of the handle substrate and/or the semiconductor layer may be {100}, {110}, or {111}. Other crystallographic orientations besides those specifically mentioned can also be used in the present disclosure. The handle substrate and/or the semiconductor layer of the SOI substrate may be a single crystalline semiconductor material, a polycrystalline material, or an amorphous material. Typically, at least the semiconductor layer is a single crystalline semiconductor material.

The buried insulating layer of the SOI substrate may be a crystalline or non-crystalline oxide or nitride. In one embodiment, the buried insulating layer is an oxide. The buried insulating layer may be continuous or it may be discontinuous. When a discontinuous buried insulating region is present, the insulating region exists as an isolated island that is surrounded by semiconductor material.

The SOI substrate may be formed utilizing standard processes including for example, SIMOX (separation by ion implantation of oxygen) or layer transfer. When a layer transfer process is employed, an optional thinning step may follow the bonding of two semiconductor wafers together. The optional thinning step reduces the thickness of the semiconductor layer to a layer having a thickness that is more desirable.

The thickness of the semiconductor layer of the SOI substrate is typically from 100 Å to 1000 Å, with a thickness from 500 Å to 700 Å being more typical. In some embodiments, and when an ETSOI (extremely thin semiconductor-on-insulator) substrate is employed, the semiconductor layer of the SOI has a thickness of less than 100 Å. If the thickness of the semiconductor layer is not within one of the above mentioned ranges, a thinning step such as, for example, planarization or etching can be used to reduce the thickness of the semiconductor layer to a value within one of the ranges mentioned above.

The buried insulating layer of the SOI substrate typically has a thickness from 10 Å to 2000 Å, with a thickness from 1000 Å to 1500 Å being more typical. The thickness of the handle substrate of the SOI substrate is inconsequential to the present disclosure.

In some other embodiments, hybrid semiconductor substrates which have different surface regions of different crystallographic orientations can be employed as semiconductor substrate 12. When a hybrid substrate is employed, an nFET is typically formed on a (100) crystal surface, while a pFET is typically formed on a (110) crystal plane. The hybrid substrate can be formed by techniques that are well known in the art. See, for example, U.S. Pat. No. 7,329,923, U.S. Publication No. 2005/0116290, dated Jun. 2, 2005 and U.S. Pat. No. 7,023,055, the entire contents of each are incorporated herein by reference.

The semiconductor substrate 12 may be doped, undoped or contain doped and undoped regions therein. For clarity, the doped regions are not specifically shown in the drawings of the present application. Each doped region within the semiconductor substrate 12 may have the same, or they may have different conductivities and/or doping concentrations. The doped regions that are present in the semiconductor substrate 12 are typically referred to as well regions and they are formed utilizing a conventional ion implantation process or gas phase doping.

The semiconductor substrate 12 can be processed to include at least one isolation region therein. For clarity, the at least one isolation region is not shown in the drawings of the present disclosure. The at least one isolation region can be a trench isolation region or a field oxide isolation region. The trench isolation region can be formed utilizing a conventional trench isolation process well known to those skilled in the art. For example, lithography, etching and filling of the trench with a trench dielectric such as an oxide may be used in forming the trench isolation region. Optionally, a liner may be formed in the trench prior to trench fill, a densification step may be performed after the trench fill and a planarization process may follow the trench fill as well. The field oxide isolation region may be formed utilizing a so-called local oxidation of silicon process. Note that the at least one isolation region provides isolation between neighboring gate structure regions, typically required when the neighboring gates have opposite conductivities, i.e., nFETs and pFETs. As such, the at least one isolation region separates an nFET device region from a pFET device region.

As stated above, the structure 10 also includes a plurality of gate structures 20 located on an uppermost surface 11 of a semiconductor substrate 12. In some embodiments of the present disclosure, each gate structure 20 may have a same conductivity, i.e., nFETs or pFETs. In another embodiment, a first set of gate structures 20 may have a first conductivity, i.e., nFETs or pFETs, and a second set of gat structures 20 may have a second conductivity which is opposite from the first conductivity (i.e., nFETs or pFETs not present in the first set).

Each gate structure 20 includes a material stack of, from bottom to top, a gate dielectric layer portion 14, a gate conductor layer portion 16, and an optional hard mask material layer portion 18. In some embodiments, the optional hard mask material layer portion 18 can be omitted. Each gate structure 20 may contain other materials including but not limited to work function adjusting materials.

The gate dielectric layer portion 14 of each gate structure 20 can be composed of a dielectric material such as, for example, silicon oxide, silicon nitride, silicon oxynitride, a dielectric metal oxide or any multilayered stack thereof. Exemplary dielectric metal oxides that can be employed in the present disclosure as the gate dielectric layer portion 14 include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The dielectric metal oxides typically have a dielectric constant that is greater than that of silicon oxide. The thickness of the gate dielectric layer portion 14 can be from 1 nm to 20 nm. Other thicknesses that are lesser than or greater than the aforementioned range for the gate dielectric layer portion 14 can also be employed in the present disclosure. In some embodiments, each gate structure 20 includes a same gate dielectric layer portion 14. In other embodiments, a first set of gate structures can comprise a first gate dielectric layer portion, while a second set of gate structures can comprise a second gate dielectric portion, wherein said second gate dielectric portion comprises at least one different gate dielectric material than the first gate dielectric portion.

The gate conductor layer portion 16 of each gate structure 20 can be composed of a conductive material including, for example, doped polysilicon, a doped silicon germanium alloy, an elemental metal, an alloy containing at least two elemental metals, a metal semiconductor alloy and any multilayered combination thereof. The thickness of the gate conductor layer portion 16 can be from 50 nm to 150 nm. Other thicknesses that are lesser than or greater than the aforementioned range for the gate conductor layer portion 16 can also be employed in the present disclosure. In some embodiments, each gate structure 20 includes a same gate conductor layer portion 16. In other embodiments, a first set of gate structures can comprise a first gate conductor portion, while a second set of gate structures can comprise a second gate conductor portion, wherein said second gate conductor portion comprises at least one different gate conductor material than the first gate conductor portion.

If present, the hard mask material layer portion 18 can be comprised of a dielectric material including, for example, silicon oxide, silicon nitride, silicon oxynitride or multilayered stacks thereof. When present, the thickness of the hard mask material layer portion 18 can be from 20 nm to 100 nm. Other thicknesses that are lesser than or greater than the aforementioned range for the hard mask material layer portion 18 can also be employed in the present disclosure.

The gate structures 20 can be formed utilizing any technique known in the art. For example, and in one embodiment, the gate structures 20 can be formed by blanket depositing various material layers, and then patterning those material layers by lithography and etching. In another embodiment, the gate structures 20 can be formed utilizing a replacement gate process in which a sacrificial gate region is first formed upon the semiconductor substrate and then subsequently replaced with various material layers present within each gate structure 20.

The structure 10 shown in FIG. 1 also includes a first spacer 22 having a first edge located on a vertical sidewall of each gate structure 20 and a base that is located on the uppermost surface 11 of semiconductor substrate 12. The first spacer 22 can be composed of a dielectric insulating material such as, for example, silicon oxide, silicon nitride, or silicon oxynitride. In some embodiments, the first spacer 22 can be composed of a same material as that of the hard mask layer portion 18. In other embodiments, the first spacer 22 can be composed of a different material as that of the hard mask material layer portion 18. The first spacer 22 can be formed by deposition and etching. In some embodiments, the first spacer 22 is formed after formation of each gate structure 20. In other embodiments, and typically when a replacement gate structure is employed, the first spacer 22 is formed prior to formation of each gate structure 20. The thickness of the first spacer, as measured from its base, can be from 1 nm to 10 nm. Other thicknesses that are lesser than or greater than the aforementioned range for the first spacer 22 can also be employed in the present disclosure.

In some embodiments of the present disclosure, the pitch of the gate structures, i.e., the distance from a central portion of one gate structure to a central portion of its nearest neighboring gate structure, is from 100 nm or less. In other embodiments, the pitch of the gate structures is from 55 nm or less.

Referring now to FIG. 2, there is illustrated the structure 10 of FIG. 1 after recessing exposed portions of the semiconductor substrate 12 utilizing the gate structures 20 and first spacers 22 as an etch mask. Specifically, a recess etch that selectively removes semiconductor material compared to the materials of the first spacer 22 and the gate structures 20 is employed to the structure shown in FIG. 1. As used herein, the term “selective” in reference to a material removal process denotes that the rate of material removal for a first material is greater than the rate of removal for at least another material of the structure to which the material removal process is being applied. For example and in one embodiment, a selective etch may include an etch chemistry that removes a first material selectively to a second material by a ratio of 10:1 or greater.

In one embodiment of the present disclosure, the recess etch may include a dry etching process (including for example, reactive ion etching, plasma etching or ion beam etching) or a wet chemical etching process. In some embodiments, the recessed etch may include a crystallographic wet etch process. Examples of suitable wet etchants that can be employed in this recess etch step include, but are not limited to, KOH, tetramethylammonium hydroxide (TMAH), ethylene diamine pyrocatechol (EDP), N₂H₄, NaOH, and CsOH. Typically, a plasma etch such as, for example, a low energy downstream radical etching process is employed as the recess etch.

After completion of the recess etch, each portion of the semiconductor substrate 12 that was subjected to the recess etch has a recessed surface, rs₁, relative to that of the uppermost surface 11 of the semiconductor substrate 12 that is located beneath each first spacer 22 and each gate structure 20. Stated in other terms, the recessed surface, rs₁, is located below and vertically offset from the uppermost surface 11 of the non-etched portions of the semiconductor substrate 12. The amount of semiconductor material that is removed during the recess etch is typically from 1 nm to 10 nm. Other amounts of semiconductor material that are lesser than or greater than the aforementioned range can be also be removed by the recess etch.

Referring now to FIG. 3, there is illustrated the structure of FIG. 2 after forming a sacrificial replacement material 24 on each of the recessed surfaces rs₁. The sacrificial replacement material 24 can also be referred to herein as a replacement extension layer since it is used in forming the extension regions of the structure.

The sacrificial replacement material 24 can be composed of any material (semiconductor, insulating or conductive) that has a different etch rate than the semiconductor material of the starting semiconductor substrate 12. In one embodiment of the present disclosure, and when the semiconductor substrate 12 is composed of silicon, the sacrificial replacement material 24 is composed of a germanium-containing semiconductor material. By “germanium-containing semiconductor material” it is meant a semiconductor material that includes at least germanium. Examples germanium-containing semiconductor materials that can be employed as the sacrificial replacement material 24 include a silicon germanium alloy containing from 20 to 99.99 weight percent germanium, pure germanium, doped germanium, and multilayers thereof.

In some embodiments of the present disclosure, the sacrificial replacement material 24 may have a same crystallographic orientation as that of recessed surface of the semiconductor substrate 12. In another embodiment, the sacrificial replacement material 24 may have a different crystallographic orientation as that of recessed surface of the semiconductor substrate 12.

The sacrificial replacement material 24 can be formed utilizing a deposition process. Examples of deposition processes that can be used in forming the sacrificial replacement material 24 include, but are not limited to, chemical vapor deposition, plasma enhanced chemical vapor deposition, epitiaxial growth, and atomic layer deposition. In cases when the sacrificial replacement material 24 is doped, a dopant such as, for example, boron, can be added during or after the deposition of the sacrificial replacement material 24. When the doping occurs during the deposition process, the deposition process may be referred to as an in-situ doping deposition process. In this instance, a dopant is present as one of the precursors used in forming the sacrificial replacement material 24. When doping occurs after deposition, the dopant can be introduced into an intrinsic sacrificial replacement material 24 by ion implantation, gas phase doping or by out diffusion of the dopant from another sacrificial material that contains the dopant.

The sacrificial replacement material 24 that is formed has a thickness which is substantially equal to the amount of semiconductor material removed during the recessed etch mentioned above. By “substantially equal” it is meant that the thickness of the sacrificial replacement material 24 is within ±0.5 nm from that of the amount of semiconductor material removed by the recessed etch mentioned above. As such, the sacrificial replacement material 24 has an uppermost surface that is substantially coplanar (within ±0.5 nm) with the uppermost surface 11 of the remaining portions of the semiconductor substrate 12 that are located beneath each first spacer 22 and each gate structure 20.

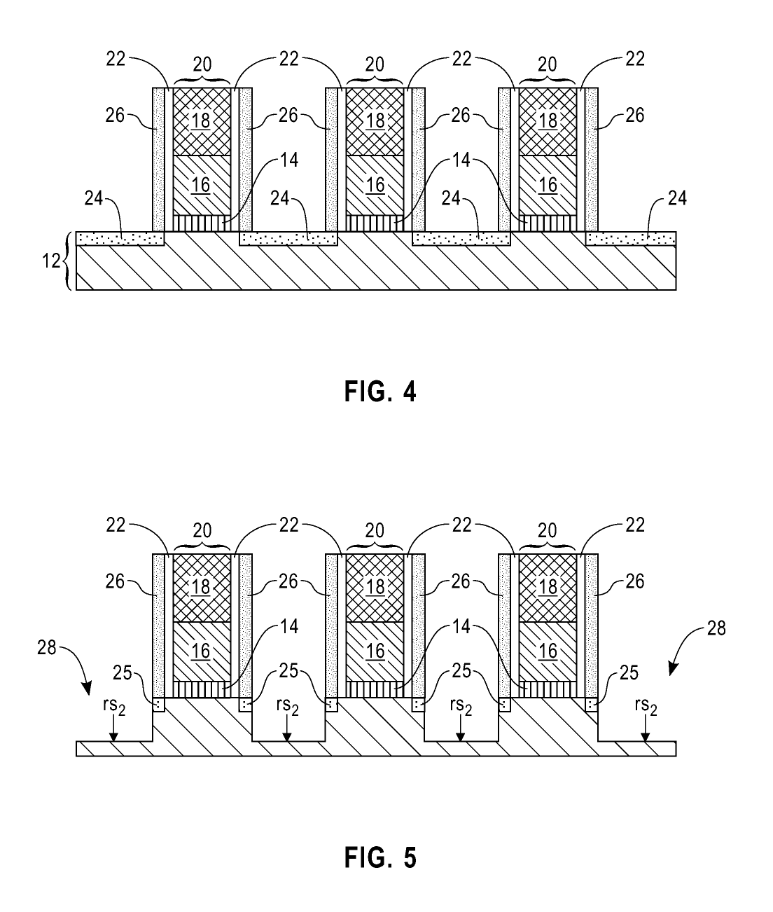

Referring now to FIG. 4, there is illustrated the structure of FIG. 3 after forming a second spacer 26 contacting the first spacer 22 and having a base that is present on the uppermost surface of the sacrificial replacement material 24. As shown an inner edge of the second spacer 26 contacts an outer edge of the first spacer 22. The second spacer 26 is comprised of a different insulator spacer material as that of the first spacer 22. The second spacer 26 may be formed utilizing the process mentioned above for the first spacer 22. The thickness of the second spacer 26, as measured from its base, is equal to or greater than the thickness of the first spacer 22. Typically, the thickness of the second spacer 26 can be from 1 nm to 20 nm. In one example, the thickness of the second spacer 26 that is employed in the present disclosure 5 nm.

Referring to FIG. 5, there is illustrated the structure of FIG. 4 after forming source/drain trenches 28 within the structure by utilizing the second spacer, the first spacer and the at least one gate structure as another etch mask and removing exposed portions of the sacrificial replacement material 24 together with an underlying portion of the semiconductor substrate 12 having recessed surfaces rs₁. This step provides a second recessed surface, rs₂, within the semiconductor substrate 12 which is deeper than the recessed surface rs₁ and the original uppermost surface 11 of the semiconductor substrate 12. Portions of the sacrificial replacement material 24 that are located directly beneath the second spacer 26 are not removed. The remaining portions of the sacrificial replacement material 24 that remain directly beneath the second spacer 26 are referred to herein as sacrificial replacement material portions 25. The source/drain trenches 28 can be formed in the present disclosure by utilizing an anisotropic etching process such as, for example, reactive-ion etching, and plasma etching.

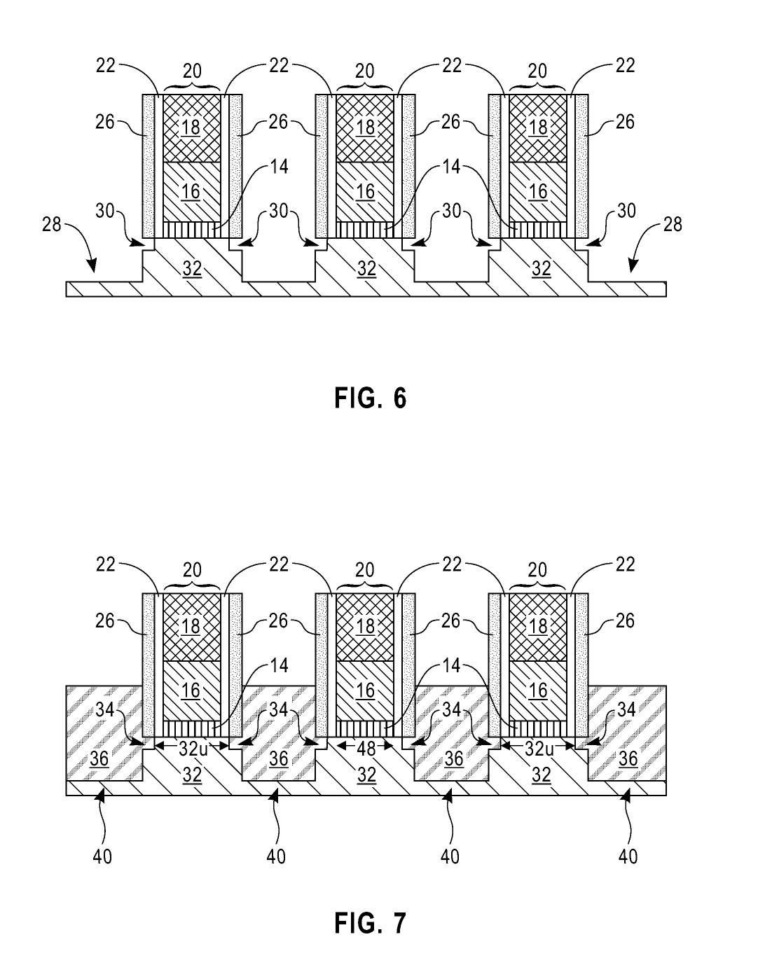

Referring now to FIG. 6, there is illustrated the structure of FIG. 5 after removing the sacrificial replacement material portions 25 from beneath each second spacer 26 to provide an opening 30 beneath the second spacer 26. A stepped mesa semiconductor structure 32 which includes the semiconductor material of the originally semiconductor substrate 12 that is located directly beneath the second spacer 26, the first spacer 22, and each gate structure 20 is also formed at this point of the present disclosure. By “stepped mesa semiconductor structure” it is meant a portion of the semiconductor substrate directly beneath the second spacer 26, the first spacer 22, and each gate structure 20 in which at least one ledge, represented by opening 30, is present between the second recessed surface rs₂ and the remaining uppermost surface 11 of the semiconductor substrate 12. As shown, the opening 30 exposes a sidewall of the stepped mesa semiconductor structure 32 which is less than 15 nm (i.e., the width of the first spacer 22) from the channel region.

The removal of the sacrificial replacement material portions 25 from beneath each second spacer 26 can be performed utilizing an etch that is highly selective in removing the sacrificial replacement material portions 25 as compared to the semiconductor material employed as the semiconductor substrate 12. In one embodiment in which the sacrificial replacement material portions 25 comprise a germanium-containing material, and the semiconductor substrate 12 comprises Si, an RCA clean can be used. RCA clean is a standard set of wafer cleaning steps which is performed before high-temperature processing steps. The RCA clean includes a first step of removal of organic contaminants (Organic Clean), a second step of removal of a thin oxide layer (Oxide Strip); and a third step of removal of ionic contaminations (Ionic Clean). Typically, the RCA clean comprises a first step (called SC-1, where SC stands for standard clean) in which the structure is contacted with a 1:1:5 solution of NH₄OH (ammonium hydroxide)+H₂O₂ (hydrogen peroxide)+H₂O (water) at 75° C. or 80° C. typically for 10 minutes. This treatment results in the formation of a thin silicon dioxide layer (about 10 Angstrom) on the silicon surface, along with a certain degree of metallic contamination that shall be removed in subsequent steps. Next, a second step is performed by immersing the structure in a 1:50 solution of HF+H₂O at 25° C., in order to remove the thin oxide layer and some fraction of ionic contaminants. The third and last step (called SC-2) is performed by contacting the structure with a 1:1:6 solution of HCl+H₂O₂+H₂O at 75° C. or 80° C. This treatment effectively removes the remaining traces of metallic (ionic) contaminants.

In one embodiment in which the sacrificial replacement material portions 25 comprise a germanium-containing material, and the semiconductor substrate 12 comprises Si, an etch using HCl vapor at a temperature from 300° C. to 750° C. In one example, the etch in HCl vapor can be performed at a temperature of 600° C.

In a second embodiment in which the sacrificial replacement material portions 25 comprise a germanium-containing material, and the semiconductor substrate 12 comprises Si, another selective removal process using a high pressure oxidation (HIPOX) process followed by a DHF oxide removal can be performed.

Referring now to FIG. 7, there is illustrated the structure of FIG. 6 after formation of a doped semiconductor material within the source/drain trenches 28 and the opening 30 located beneath the second spacer 26. The portion of the doped semiconductor material that is within the opening 30 can be referred to as the source/drain extension regions 34, and the other portions of the doped semiconductor material that are formed outside the opening 30 and directly within the source/drain trenches 28 can be referred to herein as the source/drain regions 36. The source/drain extension regions 34 and the source/drain regions 36 are of unitary construction, as such no interface is present between the two diffusion regions. Element 48 shown with respect to the middle gate structure denotes the channel region which is present in an uppermost section 32u of the at least one at least one stepped mesa semiconductor structure 32 and located directly beneath the gate structure. A channel region would also be located in the corresponding spot in each of the gate structures that are formed.

The doped semiconductor material can be formed utilizing an epitaxial growth process in which an undoped or in-situ doped semiconductor material is formed. In an in-situ doping process, the dopant is added during the deposition of the semiconductor material. Doping can be introduced after epitaxial growth (ex-situ) utilizing ion implantation, gas phase doping or dopant out diffusion from a sacrificial dopant source material.

“Epitaxially growing, epitaxial growth and/or deposition” mean the growth of a semiconductor material on a deposition surface of a semiconductor material, in which the semiconductor material being grown has the same crystalline characteristics as the semiconductor material of the deposition surface. In the present embodiment, the semiconductor material used in forming source/drain regions 36 has the same crystalline characteristics as that of the exposed recessed second surface rs₂ of the semiconductor substrate 12. When the chemical reactants are controlled and the system parameters set correctly, the depositing atoms arrive at the deposition surface with sufficient energy to move around on the surface and orient themselves to the crystal arrangement of the atoms of the deposition surface. Thus, an epitaxial film deposited on a {100} crystal surface will take on a {100} orientation. In some embodiments, the epitaxial deposition process is a selective deposition process.

The semiconductor material that can be epitaxially deposited includes any semiconductor material such as, for example, silicon (Si), germanium (Ge), and silicon germanium (SiGe). In one embodiment, the semiconductor material that is epitaxially deposited includes a same semiconductor material as that of semiconductor substrate 12. In another embodiment, the semiconductor material includes a different semiconductor material as that of the semiconductor substrate 12. It is noted that the specific material compositions for the semiconductor material are provided for illustrative purposes only, and are not intended to limit the present disclosure, as any semiconductor material that may be formed using an epitaxial growth process.

A number of different sources may be used for the deposition of semiconductor material used in forming the source/drain extension regions 34 and the source/drain regions 36. In some embodiments, in which the semiconductor material of the source/drain extension regions 34 and the source/drain regions 36 is composed of silicon, the silicon gas source for epitaxial deposition may be selected from the group consisting of hexachlorodisilane (Si₂Cl₆), tetrachlorosilane (SiCl₄), dichlorosilane (Cl₂SiH₂), trichlorosilane (Cl₃SiH), methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄), hexamethyldisilane ((CH₃)₆Si₂) and combinations thereof. In some embodiments, in which semiconductor material of the source/drain extension regions 34 and the source/drain regions 36 is composed of germanium, the germanium gas source for epitaxial deposition may be selected from the group consisting of germane (GeH₄), digermane (Ge₂H₆), halogermane, dichlorogermane, trichlorogermane, tetrachlorogermane and combinations thereof. In some embodiments, in which the semiconductor material the source/drain extension regions 34 and the source/drain regions 36 is composed of silicon germanium, the silicon sources for epitaxial deposition may be selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof, and the germanium gas sources may be selected from the group consisting of germane, digermane, halogermane, dichlorogermane, trichlorogermane, tetrachlorogermane and combinations thereof.

The temperature for epitaxial semiconductor deposition typically ranges from 550° C. to 1300° C. The apparatus for performing the epitaxial growth may include a chemical vapor deposition (CVD) apparatus, such as atmospheric pressure CVD (APCVD), low pressure CVD (LPCVD), plasma enhanced CVD (PECVD), metal-organic CVD (MOCVD), RTCVD and others. As stated above, the epitaxial semiconductor material that is deposited can be doped or undoped. By “undoped” it is meant that the maximum dopant concentration of p-type or n-type dopants that are present in the epitaxial semiconductor material is less than 5×10¹⁷ atoms/cm³.

Notwithstanding whether the semiconductor material is doped in-situ, or ex-situ, the source/drain extension regions 34 and the source/drain regions 36 have a dopant concentration from 10²¹ atoms/cm³ or greater.

Specifically, FIG. 7 illustrates the resultant semiconductor structure of the present disclosure. The structure includes a semiconductor substrate 12 comprising at least one stepped mesa semiconductor structure 32 and adjoining recessed surface semiconductor portions 40. At least one gate structure 20 is located on an uppermost surface 11 of the at least one stepped mesa semiconductor structure 32. A first spacer 22 is present on vertical sidewalls of the at least one gate structure 20 and has a base in contact with the uppermost surface 11 of the at least one stepped mesa semiconductor structure 32. A second spacer 26 is located adjacent the first spacer 22, and a base of the second spacer 26 is present on an uppermost surface of a source/drain extension region 34. The source/drain extension region 34 has a bottommost surface located on a ledge portion of the at least one stepped mesa semiconductor structure 32. A source/drain region 36 is located on each of the recessed surface semiconductor portions 40 of the semiconductor substrate 12. In accordance with the present disclosure, the source/drain region 36 and the source/drain extension region 34 are of unitary construction and comprise a same doped semiconductor material, and the source/drain extension region 34 is located from 10 nm or less from a channel region 48 located within a portion of the at least one stepped mesa semiconductor structure 32 and directly beneath the at least one gate structure 20. In some embodiments, the source/drain extension region 34 is located from 1 nm or less from the channel region 48. As shown in FIG. 7, an outermost edge of the first spacer 22 is vertical coincident to an uppermost section 32u of the at least one at least one stepped mesa semiconductor structure 32. In the disclosed structure shown in FIG. 7, the source/drain extension region 34 has a width equal to a width of the second spacer 26.

In some embodiments of the present disclosure, any combinations including both of the extension region 34 and the source/drain region 36 may include either carbon up to 50% content or germanium up to 85% content in order to induce uniaxial strain to channel region 48 thereby improving the carrier mobility of either electrons or holes in the strained channel region 48.

While the present disclosure has been particularly shown and described with respect to preferred embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

1. A method of forming a semiconductor structure comprising:
providing at least one gate structure on an uppermost surface of a semiconductor substrate, said at least one gate structure having a first spacer located on a vertical sidewall thereof and having a base contacting a portion of the uppermost surface of the semiconductor substrate;
recessing exposed portions of the semiconductor substrate to a first depth utilizing the at least one gate structure and first spacer as an etch mask;
depositing a sacrificial replacement material on each recessed surface of the semiconductor substrate, wherein an entirety of an uppermost surface of said sacrificial replacement material is coplanar with, or located beneath, an uppermost surface of a remaining portion of said semiconductor substrate that is located directly beneath said at least one gate structure and said first spacer, and wherein no portion of said sacrificial replacement material contacts a sidewall surface of said first spacer;
forming a second spacer contacting the first spacer and having a base that is present on the uppermost surface of the sacrificial replacement material;
forming source/drain trenches to a second depth that is less than the first depth by removing exposed portions of the sacrificial replacement material and an underlying portion of the semiconductor substrate utilizing the second spacer, the first spacer and the at least one gate structure as another etch mask, wherein a sacrificial replacement material portion remains beneath the second spacer;
removing the sacrificial replacement material portion from beneath the second spacer to provide an opening beneath the second spacer; and
forming a doped semiconductor material within the source/drain trenches and the opening located beneath the second spacer.

2. The method of claim 1, wherein said recessing the exposed portions of the semiconductor substrate is performed utilizing a wet chemical etching process.

3. The method of claim 1, wherein said recessing the exposed portions of the semiconductor substrate is performed utilizing a plasma process.

4. The method of claim 1, wherein said semiconductor substrate comprises silicon and said sacrificial replacement material comprises a germanium-containing semiconductor material.

5. The method of claim 4, wherein said germanium-containing semiconductor material is selected from a silicon germanium alloy, pure germanium, doped germanium and multilayers thereof.

6. The method of claim 1, wherein said depositing said sacrificial replacement material comprises chemical vapor deposition, plasma enhanced chemical vapor deposition, epitaxial deposition or atomic layer deposition.

7. The method of claim 1, wherein said depositing said sacrificial replacement material comprises an in-situ doping deposition process.

8. The method of claim 1, wherein said depositing said sacrificial replacement material comprises forming an intrinsic sacrificial replacement material and then subjecting the intrinsic sacrificial replacement material to a doping process.

9. The method of claim 1, wherein said forming said source/drain trenches comprises an anisotropic etching process.

10. The method of claim 1, wherein said removing said sacrificial replacement material portion from beneath the second spacer to provide said opening beneath the second spacer comprises a cleaning process, said cleaning process comprises first contacting with a 1:1:5 solution of ammonium hydroxide+hydrogen peroxide+water at 75° C. or 80° C., immersing in a 1:50 solution of HF+H₂O at 25° C., and second contacting with a 1:1:6 solution of HCl+H₂O₂+H₂O at 75° C. or 80° C.

11. The method of claim 1, wherein said removing said sacrificial replacement material portion from beneath the second spacer to provide said opening beneath the second spacer comprises an etch using HCl vapor at a temperature from 300° C. to 750° C.

12. The method of claim 1, wherein said forming the doped semiconductor material comprises an epitaxial growth.

13. The method of claim 12, wherein a portion of said doped semiconductor material located directly beneath the second spacer and within the opening is a source/drain extension region, and wherein another portion of the doped semiconductor material located in the source/drain trenches is a source/drain region, and wherein said source/drain extension region and said source/drain region are of unitary construction.

14. The method of claim 1, wherein an uppermost surface of the source/drain region extends above the uppermost surface of the semiconductor substrate.

15. The method of claim 1, wherein said removing the sacrificial replacement material portion from beneath the second spacer further provides at least one stepped mesa semiconductor structure within the semiconductor substrate.

16-25. (canceled)

26. The method of claim 1, wherein said sacrificial replacement material is non-doped.

27. The method of claim 1, wherein said doped semiconductor material comprises a same semiconductor material as said semiconductor substrate.

28. A method of forming a semiconductor structure comprising:
providing at least one gate structure on an uppermost surface of a semiconductor substrate, said at least one gate structure having a first spacer located on a vertical sidewall thereof and having a base contacting a portion of the uppermost surface of the semiconductor substrate;
recessing exposed portions of the semiconductor substrate to a first depth utilizing the at least one gate structure and first spacer as an etch mask;
depositing a sacrificial replacement material on each recessed surface of the semiconductor substrate, wherein said sacrificial replacement material is selected from the group consisting of an insulator material and a conductive material;
forming a second spacer contacting the first spacer and having a base that is present on the uppermost surface of the sacrificial replacement material;
forming source/drain trenches to a second depth that is less than the first depth by removing exposed portions of the sacrificial replacement material and an underlying portion of the semiconductor substrate utilizing the second spacer, the first spacer and the at least one gate structure as another etch mask, wherein a sacrificial replacement material portion remains beneath the second spacer;
removing the sacrificial replacement material portion from beneath the second spacer to provide an opening beneath the second spacer; and
forming a doped semiconductor material within the source/drain trenches and the opening located beneath the second spacer.

29. A method of forming a semiconductor structure comprising:
providing at least one gate structure on an uppermost surface of a semiconductor substrate, said at least one gate structure having a first spacer located on a vertical sidewall thereof and having a base contacting a portion of the uppermost surface of the semiconductor substrate;
recessing exposed portions of the semiconductor substrate to a first depth utilizing the at least one gate structure and first spacer as an etch mask;
depositing a sacrificial non-doped semiconductor material on each recessed surface of the semiconductor substrate;
forming a second spacer contacting the first spacer and having a base that is in directly physical contact with the uppermost surface of the sacrificial non-doped semiconductor material;
forming source/drain trenches to a second depth that is less than the first depth by removing exposed portions of the sacrificial non-doped semiconductor material and an underlying portion of the semiconductor substrate utilizing the second spacer, the first spacer and the at least one gate structure as another etch mask, wherein a sacrificial non-doped semiconductor material portion remains beneath the second spacer;
removing the sacrificial non-doped semiconductor material portion from beneath the second spacer to provide an opening beneath the second spacer; and
forming a doped semiconductor material within the source/drain trenches and the opening located beneath the second spacer.
